(19) United States
(12) Patent Application Publication
(10) Pub. No.: US 2026/0185224 A1
(43) Pub. Date: Jul. 2, 2026

(54) METHODS OF DEPOSITING A METAL-CONTAINING MATERIAL

(71) Applicant: ASM IP Holding B.V., Almere (NL)

(72) Inventors: Ren Qiu, Helsinki (FI); Janne-Petteri Niemelä, Helsinki (FI); Chiyu Zhu, Helsinki (FI); Antareep Sharma, Helsinki (FI); Jan Willem Maes, Wilrijk (BE); Shinya Iwashita, Brussels (BE); Maria Kim, Kirkkonummi (FI); Charles Dezelah, Helsinki (FI)

(21) Appl. No.: 19/432,375

(22) Filed: Dec. 24, 2025

Related U.S. Application Data
(60) Provisional application No. 63/739,920, filed on Dec. 30, 2024.

(51) Int. Cl. C23C 16/455; C23C 16/18; C23C 16/32; H10P 14/40; H10P 14/43

(52) U.S. Cl. CPC C23C 16/45534; C23C 16/18; C23C 16/32; C23C 16/45553; H10P 14/412; H10P 14/418; H10P 14/43

(57) ABSTRACT

The current disclosure relates to methods and assemblies for a cyclic deposition process for depositing a group four to six transition metal on a substrate. The method comprises providing a substrate in a reactor chamber, introducing a metalorganic compound as a metal precursor in a vapor phase, and a Lewis acid reactant in a vapor phase to react with the metal precursor, forming the material of the transition metal on the substrate. The method may include introducing a co-reactant in a vapor phase. The disclosure further relates to semiconductor processing assemblies for executing the methods according to the disclosure.

### CROSS-REFERENCE TO RELATED APPLICATIONS

This application claims priority to U.S. Provisional Patent Application Ser. No. 63/739,920 filed Dec. 30, 2024 and titled METHODS OF DEPOSITING A METAL-CONTAINING MATERIAL, the disclosure of which is hereby incorporated by reference in its entirety.

### FIELD

The present disclosure generally relates to methods and assemblies for depositing metal-containing material by cyclic vapor deposition techniques. Such methods may be used for, for example, processing semiconductor substrates. More particularly, the disclosure relates to methods and assemblies for depositing materials comprising a group four to group six transition metals with low carbon impurity.

### BACKGROUND

Deposition of metal carbides and elemental metals with low carbon content is of interest in the manufacture of semiconductor devices.

Low-resistivity metal carbides, such as molybdenum carbide, have significant potential in the semiconductor industry due to their excellent electrical properties and thermal stability. These materials can be used in various applications, including metal-gate word lines, capacitor electrodes for dynamic random access memory (DRAM), and back-end-of-line (BEOL) interconnects and work function metals in front end of line (FEOL). The ability of the metal carbides to maintain low resistivity even at very thin thicknesses makes them ideal for the ever-shrinking semiconductor devices, where reducing resistance is crucial to enhance performance and reduce power consumption. Additionally, metal carbides can serve as effective diffusion barriers, preventing the intermixing of materials in integrated circuits. Especially the controlled deposition of such materials by ALD can find use in the industry, enabling the precise and uniform deposition of metal carbide materials, ensuring their integration into next-generation semiconductor technologies.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of depositing metal-containing materials. Embodiments of the current disclosure further relate to methods of fabricating semiconductor devices, and to semiconductor processing assemblies.

Various embodiments of the current disclosure relate to methods of depositing material comprising a group four to group six transition metal on a substrate, to group four to group six transition metal comprising materials and semiconductor processing assemblies for depositing said materials.

In one aspect, a method for depositing a material comprising a group four to six transition metal on a substrate by a cyclic deposition process is disclosed. The method comprises providing a substrate in a reactor chamber, and providing a metal precursor comprising a metalorganic compound into the reaction chamber in a vapor phase. The method further comprises providing a Lewis acid reactant into the reaction chamber in a vapor phase to react with the metal precursor and to form the material comprising the transition metal from any of groups four to six on the substrate.

In some embodiments, the method further comprises providing a co-reactant into the reaction chamber in a vapor phase.

In some embodiments, the metalorganic compound comprises a metal selected from a group consisting of vanadium, niobium, tantalum, chromium, molybdenum and tungsten.

In some embodiments, the metal precursor comprises a zero-valence metalorganic compound. In some embodiments, the metal precursor comprises a bis-arene complex.

In some embodiments, the Lewis acid reactant comprises an inorganic halide. In some embodiments, the Lewis acid reactant is selected from a group consisting of metal halides and nonmetal halides.

In some embodiments, the inorganic halide is a chloride. In some embodiments, the inorganic halide is a metal halide selected from a group consisting of aluminum chloride, molybdenum chloride, iron chloride, and titanium tetrachloride. In some embodiments, the Lewis acid reactant comprises a group 13 element and one or more ligands selected from a halide, an alkoxide, an alkyl, a dialkylamide and combinations thereof.

In some embodiments, the material comprising a group four to six transition metal comprises a metal carbide.

In some embodiments, the co-reactant is selected from a group consisting of halosilanes, alkyl halides and acyl halides.

In some embodiments, the co-reactant comprises an alkyl halide comprising 1,2-diiodoethane or iodobutane.

In some embodiments, the co-reactant is selected from alkyl chlorides.

In some embodiments, the co-reactant is an alkyl chloride and selected from a group consisting of 1,2-dichloroethane, chloromethane, 2-chloro-2-methylpropane, trichloromethane, 2-methyl-2-chloro-butane, and tert-butyl chloride.

In some embodiments, the material comprising the group four to six transition metal comprises an elemental metal from any of groups 4 to 6 of the periodic table of elements.

In some embodiments, the metal precursor comprising a metalorganic compound, the Lewis acid reactant, and the co-reactant are supplied in pulses and the reaction chamber is purged after consecutive pulses of the Lewis acid reactant and the co-reactant.

In some embodiments, the Lewis acid reactant and the co-reactant are provided in any order.

In some embodiments, the process temperature is between about 150-400° C.

In some embodiments, the substrate comprises precleaned silicon or silicon-germanium substrate.

In some embodiments, the Lewis acid reactant is provided into the reaction chamber for a duration that is less than 2% of the length of providing the metal precursor into the reaction chamber.

In some embodiments, a semiconductor processing assembly is constructed and arranged to perform a method according to the current disclosure.

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. Likewise, when the term “consisting essentially” is used referring to a chemical compound, substance, or composition of matter, it indicates that the chemical compound, substance, or composition of matter contains the components which are listed but can also containing trace elements and/or impurities that do not materially affect the characteristics of said chemical compound, substrate, or composition of matter. This notwithstanding, the chemical compound, substance, or composition of matter may, in some embodiments, comprise other components as trace elements or impurities, apart from the components that are listed.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

The term “essentially” as applied to a composition, a method, or a system generally means that the additional components do not substantially modify the properties and/or function of the composition, the method, or the system.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure.

In the drawings

FIG. 1 is a block diagram of an exemplary embodiment of a method according to the current disclosure for depositing a material comprising a metal carbide.

FIG. 2 is a block diagram of another exemplary embodiment of a method according to the current disclosure for depositing elemental metal.

FIG. 3 is a block diagram of another exemplary embodiment of a method according to the current disclosure for depositing elemental metal.

FIG. 4 is a schematic drawing of an embodiment of a semiconductor processing assembly according to the current disclosure.

It will be appreciated that elements in the figures are illustrated for simplicity and clarity, and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION

The description of exemplary embodiments of methods, materials, layers, and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

In one aspect, a method for depositing a material comprising a group four to six transition metal on a substrate by a cyclic deposition process is disclosed. The method comprises providing a substrate in a reactor chamber, and providing a metal precursor comprising a metalorganic compound into the reaction chamber in a vapor phase. The method further comprises providing a Lewis acid reactant into the reaction chamber in a vapor phase to react with the metal precursor and to form the material comprising the transition metal from any of groups four to six on the substrate.

### Layer

The material comprising a group four to six transition metal (i.e. the metal-containing material) may be deposited as a layer. As used herein, the term “layer” and/or “film” can refer to any continuous or non-continuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous. In some embodiments, a layer according to the current disclosure is continuous.

Very thin layers with advantageous properties can be deposited with methods according to the current disclosure. In particular, the resistivity of thing films described herein may have low enough resistivity to be used in applications requiring functional layers but being very restricted in their thickness. In some embodiments, a layer of the metal-containing material has a thickness of less than 30 nm. In some embodiments, a layer of the metal-containing material has a thickness of less than 20 nm. In some embodiments, a layer of the metal-containing material has a thickness of less than 10 nm. In some embodiments, a layer of the metal-containing material has a thickness of less than 5 nm. In some embodiments, a layer of the metal-containing material has a thickness of less than 3 nm. However, in some applications, such as backside power delivery network (BSPDN) and certain memory applications (DRAM in particular) layers from about 100 nm to about 1 μm in thickness may be deposited.

### Substrate

The deposition method according to the current disclosure comprises providing a substrate in a reaction chamber. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device.

In some embodiments, the substrate surface, on which the metal-containing material according to the current disclosure is deposited comprises, consists essentially of, or consists of, silicon-germanium. In some embodiments, the substrate surface comprises, consists essentially of, or consists of a metal, such as copper, cobalt, molybdenum, ruthenium, tungsten, tantalum, niobium, vanadium or a combination thereof. The metal surface may have surface oxidation.

In some embodiments, the substrate may be pretreated or cleaned prior to or at the beginning of the deposition process. For example, a surface oxidation of a metal surface may be removed. In some embodiments, the substrate may be subjected to a plasma cleaning process at prior to or at the beginning of the deposition process. A plasma clean can comprise using plasma comprising nitrogen, such as NF₃ and/or NH₃. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the deposition process. In some embodiments, the substrate surface may be exposed to hydrogen plasma, radicals, or atomic species prior to or at the beginning of the deposition process. In some embodiments, a pretreatment or cleaning process may be carried out in the same reaction chamber as a deposition process. However, in some embodiments, a pretreatment or cleaning process may be carried out in a separate reaction chamber.

### Reaction Chamber

The method comprises providing the substrate in a reaction chamber and depositing the material comprising a group four to six transition metal on the surface of the substrate by a cyclic vapor deposition process. The method of depositing metal-containing material according to the current disclosure thus comprises providing the substrate in a reaction chamber. In other words, the substrate is in a space where the deposition conditions can be controlled. The reaction chamber may be a single wafer reactor. Alternatively, the reaction chamber may be a batch reactor. The reaction chamber can form part of a processing assembly for manufacturing semiconductor devices. The processing assembly may comprise one or more multi-station processing chambers. In some embodiments, the substrate is moved between processing stations of a multi-station processing chamber. The reaction chamber may be part of a cluster tool in which different processes are performed to form an integrated circuit. Various phases of method can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be single wafer atomic layer deposition (ALD) reactor. In some embodiments, the reaction chamber may be a high-volume manufacturing single wafer ALD reactor. In some embodiments, the reaction chamber may be a batch reactor for manufacturing multiple substrates simultaneously.

The reaction chamber can form part of a semiconductor processing assembly, such as an ALD assembly. The reaction chamber can form part of a chemical vapor deposition (CVD) assembly. The deposition assembly may be an ALD or a CVD deposition assembly, but in certain process steps, molecular layer deposition (MLD) may also be employed in some parts of the deposition process flows. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrates and/or the reactants and/or precursors.

### Cyclic Deposition Process

The vapor deposition process according to the current disclosure is a cyclic deposition process. Generally, in cyclic deposition processes according to the current disclosure, such as in atomic layer deposition (ALD), during each cycle, a precursor, such as a metal precursor, is introduced to a reaction chamber in a vapor phase and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor, such as a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a first precursor, such as a metal precursor, into the reaction chamber. In some embodiments, the cyclic deposition process comprises purging the reaction chamber after providing a second precursor or a reactant, such as a Lewis acid reactant into the reaction chamber. In some embodiments, the cyclic deposition process comprises purging the reaction chamber after providing a first precursor into the reaction chamber, and after providing a second precursor into the reaction chamber. Without limiting the current disclosure to any specific theory, ALD may contain self-limiting reactions and slower and more controllable layer growth speed compared to CVD.

The process may comprise one or more cyclic phases. In some embodiments, the process comprises or one or more acyclic (i.e. continuous) phases. In some embodiments, the deposition process comprises the continuous flow of at least one precursor or a reactant. In such an embodiment, the process comprises a continuous flow of at least the metal precursor or the Lewis acid reactant or the co-reactant. In some embodiments, one or more of the precursors and reactants are provided in the reaction chamber continuously.

The vapor deposition process according to the current disclosure comprises providing a metal precursor into the reaction chamber in a vapor phase and providing a Lewis acid reactant into the reaction chamber in a vapor phase. In some embodiments, the method comprises providing a co-reactant into the reaction chamber in a vapor phase. In some embodiments, at least one of metal precursor and Lewis acid reactant and co-reactant is provided to the reaction chamber in pulses. In some embodiments, the metal precursor is supplied in pulses and the Lewis acid reactant is supplied in pulses, and the reaction chamber is purged between consecutive pulses of metal precursor and Lewis acid reactant. In some embodiments, the metal precursor is supplied in pulses and the Lewis acid reactant is supplied in pulses and the co-reactant is supplied in pulses, and the reaction chamber is purged between consecutive pulses of metal precursor, Lewis acid reactant and co-reactant.

The metal precursor, the Lewis acid reactant and the optional co-reactant may be provided in any order. In some embodiments, a deposition cycle comprises first providing the metal precursor and then providing the Lewis acid reactant. In some embodiments, a deposition cycle comprises first providing the Lewis acid reactant and then providing the metal precursor. In some embodiments, a deposition cycle comprises first providing the metal precursor, then providing the Lewis acid reactant, and then providing the co-reactant. In some embodiments, a deposition cycle comprises first providing the metal precursor, then providing the co-reactant and then providing the Lewis acid reactant. In some embodiments, a deposition cycle comprises first providing the Lewis acid reactant, then providing the metal precursor and then providing the co-reactant. In some embodiments, a deposition cycle comprises first providing the Lewis acid reactant, then providing the co-reactant and then providing the metal precursor. In some embodiments, a deposition cycle comprises first providing the co-reactant, then providing the metal precursor and then providing the Lewis acid reactant. In some embodiments, a deposition cycle comprises first providing the co-reactant, then providing the Lewis acid reactant and then providing the metal precursor. In some embodiments, the Lewis acid reactant is provided into the reaction chamber at least partially simultaneously with the co-reactant. Without limiting the current disclosure to any specific theory, the Lewis acid reactant may catalyze the reaction between the metal precursor and the co-reactant, leading to a faster reaction that favors the formation of pure elemental metal. This may reduce carbon incorporation in the deposited material, leading to higher elemental metal content and increased electrical conductivity of the deposited material. The use of a Lewis acid reactant may allow the use of a lower reaction temperature and/or fasted cycling for a given material quality. Further, the pressure in the reaction chamber may be reduced. Such advantages may translate into more economical and environmentally friendly deposition processes through lowered energy and process gas consumption during manufacture of semiconductor devices. The improved material quality can reduce the energy consumption of the final product in which materials according to the current disclosure are used.

A duration of providing metal precursor and/or a Lewis acid reactant and/or co-reactant into the reaction chamber (i.e. metal precursor pulse time, Lewis acid reactant pulse time and co-reactant pulse time, respectively) may be, for example, from about 0.01 s to about 60 s, for example from about 0.01 s to about 10 s, or from about 0.5 s to about 20 s, or from about 0.5 s to about 10 s, or from about 2 s to about 15 s, or from about 10 s to about 30 s, or from about 10 s to about 60 s, or from about 20 s to about 60 s. The duration of metal precursor or a Lewis acid reactant pulse may be, for example 0.01 s, 0.02 s, 0.05 s, 0.1 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, metal precursor pulse time may be at least 3 seconds, or at least 5 seconds. In some embodiments, metal precursor pulse time may be at most 5 seconds, or at most 10 seconds or at most 20 seconds, or at most 30 seconds. In some embodiments, Lewis acid reactant pulse time is at least 0.005 seconds, or at least 0.01 seconds, or at least 0.02 seconds, or at least 0.05 seconds. In some embodiments, Lewis acid reactant pulse time may be at most 0.02 seconds, or at most 0.05 seconds or at most 0.1 seconds, or at most 0.5 seconds. Controlling the dose of the Lewis acid reactant is of particular interest, as it too high a dose can lead into decrease of the properties of the deposited material, and unwanted incorporation of the constituents of the Lewis acid reactant into the deposited material.

The pulse times for metal precursor, for Lewis acid reactant and for the optional co-reactant can vary independently according to process in question. For example, the flow rate of the precursor or reactant influence the optimal pulse length of the precursor or reactant. The selection of an appropriate pulse time may depend on the substrate topology. For higher aspect ratio structures, longer pulse times may be needed to obtain sufficient surface saturation in different areas of a high aspect ratio structure. Also the selected metal precursor, Lewis acid reactant and co-reactant chemistries may influence suitable pulsing times. For process optimization purposes, shorter pulse times might be preferred as long as appropriate layer properties can be achieved. In some embodiments, metal precursor pulse time is longer than Lewis acid reactant pulse time. In some embodiments, Lewis acid reactant pulse time is longer than metal precursor pulse time. In some embodiments, metal precursor pulse time is the same as Lewis acid reactant pulse time. In some embodiments, co-reactant pulse time is longer than Lewis acid reactant pulse time. In some embodiments, Lewis acid reactant pulse time is longer than co-reactant pulse time. In some embodiments, co-reactant pulse time is longer than metal precursor pulse time. In some embodiments, metal precursor pulse time is longer than co-reactant pulse time. In some embodiments, co-reactant pulse time is the same as metal precursor pulse time. In some embodiments, co-reactant pulse time is the same as Lewis acid reactant pulse time.

In some embodiments, providing metal precursor and/or a Lewis acid reactant and/or a co-reactant into the reaction chamber comprises pulsing the metal precursor and the Lewis acid reactant and the optional co-reactant over a substrate. In certain embodiments, pulse times in the range of several minutes may be used for the metal precursor and/or the Lewis acid reactant. In some embodiments, metal precursor may be pulsed more than one time, for example two, three or four times, before a Lewis acid reactant and the optional co-reactant is pulsed to the reaction chamber. Similarly, there may be more than one pulse, such as two, three or four pulses, of a Lewis acid reactant and/or the optional co-reactant before metal precursor is pulsed (i.e. provided) into the reaction chamber. In some embodiments, the metal precursor, the Lewis acid reactant, and the co-reactant are supplied in pulses and the reaction chamber is purged after consecutive pulses of the Lewis acid reactant and the co-reactant.

A pulse of a metal precursor and a Lewis acid reactant may together form a deposition cycle. A pulse of a metal precursor and a Lewis acid reactant and a co-reactant may together form a deposition cycle. As described above, the process is a cyclic deposition process. Thus, providing (i.e. pulsing) the precursors into the reaction chamber is repeated. The pulses may be repeated as desired, depending on, for example, on the growth rate of the metal-containing material, and on the intended thickness of the metal-containing material. In some embodiments, the growth rate of the metal-containing material is from about 0.1 Å/cycle per cycle to about 10 Å/cycle, such as from about 4 Å/cycle to about 9 Å/cycle. In some embodiments, the growth rate of the metal-containing material is from about 0.1 Å/cycle to about 5 Å/cycle, such as about 3 Å/cycle or about 4 Å/cycle. In some embodiments, the growth rate of the metal-containing material is from about 1 Å/cycle to about 3.5 Å/cycle, such as about 2 Å/cycle or about 3 Å/cycle. In some embodiments, the growth rate of the metal-containing material is from about 0.1 Å/cycle to about 1.5 Å/cycle, such as about 0.3 Å/cycle or about 0.8 Å/cycle. In some embodiments, the growth rate of the metal-containing material is from about 0.1 Å/cycle to about 1 Å/cycle, such as about 0.7 Å/cycle or about 0.9 Å/cycle. In some embodiments, the growth rate of the metal-containing material is from about 0.5 Å/cycle to about 1 Å/cycle.

The thickness of the metal-containing material may be selected according to the application in question. In some embodiments, the deposited metal-containing material has a thickness from about 0.1 nm to about 30 nm. Thus, depending on the growth rate of the metal-containing material, the deposition cycle may be performed from about 2 to about 800 times. For example, a deposition cycle may be performed about 10, 20, 50, 100, 200, 300, 500, 600 or 700 times.

In some embodiments, the metal-containing material according to the current disclosure is deposited at a pressure of at least 0.01 Torr to at most 100 Torr, or at a pressure of at least 0.1 Torr to at most 50 Torr, or at a pressure of at least 0.5 Torr to at most 25 Torr, or at a pressure of at least 0.1 Torr to at most 10 Torr, or at a pressure of at least 0.1 Torr to at most 5 Torr. In some embodiments, the metal-containing material according to the current disclosure is deposited at a pressure of at least 0.5 Torr to at most 20 Torr, or at a pressure of at least 1 Torr to at most 15 Torr, or at a pressure of at least 1 Torr to at most 10 Torr, For example, the metal-containing material may be deposited at a pressure of about 0.5 Torr, about 1 Torr, about 2 Torr, about 3 Torr, about 6 Torr, about 8 Torr, about 9 Torr, about 12 Torr or about 18 Torr.

In some embodiments, the cyclic deposition process according to the current disclosure comprises a thermal deposition process. In thermal deposition, the chemical reactions are promoted by increased temperature relevant to ambient temperature (process temperature). Generally, temperature increase provides the energy needed for the formation of the target material in the absence of other external energy sources, such as plasma, radicals, or other forms of radiation. In some embodiments, the method according to the current disclosure comprises a plasma-enhanced deposition method, for example PEALD or PECVD. For example, in some embodiments, the metal-containing material deposition may be performed by PEALD or PECVD.

### Metal Precursor

In the methods according to the current disclosure, a metal precursor comprising a metalorganic compound is provided into the reaction chamber in a vapor phase. The metal precursors according to the current disclosure comprises a metal from any of groups four, five or six of the periodic table of elements. The metal precursor further comprises an organic ligand that may be bonded to the metal atom through a carbon atom or through another atom, such as an oxygen atom or a nitrogen atom. The metal precursor according to the current disclosure comprises a metalorganic compound.

In the current disclosure, a metalorganic compound is to be understood as a compound containing carbon and metal. The metal may be bonded to the rest of the compound through a carbon atom, or through an atom of another element, such as oxygen or nitrogen.

In some embodiments, the metal atom in the metalorganic compound has an oxidation state of zero. Such compounds can be called zero-valence compounds. In some embodiments, the metal precursor comprises a zero-valence metalorganic compound. In some embodiments, the metal has an oxidation state higher than zero, but lower than the highest oxidation state of the metal. Such compounds can be called low-valence compounds. In some embodiments, the metal precursor comprises a low-valence metalorganic compound. In some embodiments, the valence of the metal in the metalorganic compound has a lower oxidation state than its group number. Thus, in some embodiments, the metalorganic compound comprises a group four metal, and the metal has an oxidation state lower than four. In some embodiments, the metalorganic compound comprises a group five metal, and the metal has an oxidation state lower than five. In some embodiments, the metalorganic compound comprises a group six metal, and the metal has an oxidation state lower than six. In some embodiments, the metal precursor comprises a metal selected from a group consisting of titanium, zirconium, hafnium, vanadium, niobium, tantalum, chromium, molybdenum and tungsten. In some embodiments the metal precursor is selected from one or more of a titanium precursor, a zirconium precursor, a hafnium precursor, a vanadium precursor, a niobium precursor, a tantalum precursor, a chromium precursor, a molybdenum precursor and a tungsten precursor. In some embodiments, the metal precursor is selected from a group consisting of molybdenum precursor, niobium precursor and tungsten precursor.

In some embodiments, metalorganic compound comprises a cyclopentadienyl ligand. In some embodiments, the metalorganic compound comprises a carbonyl group-containing ligand. In some embodiments, the metalorganic compound comprises a cycloheptatrienyl (CHT) ligand. In some embodiments, the metalorganic compound comprises a diazadiene ligand, such as a N, N′-diisopropyldiazadiene or N, N′-di-tert-butyldiazadiene ligand. In some embodiments, the metalorganic compound comprises a phosphine ligand. In some embodiments, the metalorganic compound comprises an alkyl ligand. In some embodiments, the metalorganic compound comprises an aryl ligand. In some embodiments, the metalorganic compound comprises an arene ligand. In some embodiments, the metalorganic compound comprises a η⁶-coordinated arene ligand. In some embodiments, the metalorganic compound is a homoleptic bis-arene compound. In some embodiments, the metalorganic compound comprises an amidinato ligand. In some embodiments, the metalorganic compound comprises a nitrosyl ligand. In some embodiments, the metalorganic compound is a heteroleptic compound. In some embodiments, the metalorganic compound is a zero-valence compound. In some embodiments, the zero-valence compound is selected from arene ligand-comprising compounds and carbonyl ligand-comprising compounds.

In particular, in some embodiments, the metalorganic compound comprises a complex of a bis(arene) and a metal selected from a group consisting of V, Cr, Mo and W. In some embodiments, the metalorganic compound comprises a homoleptic carbonyl compound. In some embodiments, the metalorganic compound comprises a metal selected from Mo and W, two Cp ligands and two H ligands. In some embodiments, the metalorganic compound comprises a metal selected from Mo and W, one arene ligand and three carbonyl ligands. In some embodiments, the metalorganic compound comprises vanadium metal and four amido ligands.

In some embodiments, the metal precursor is a titanium precursor and deposited metal-containing material comprises titanium. In some embodiments, the titanium precursor comprises, consists essentially of, or consists of a metalorganic compound selected from, for example, Ti(NEt₂)₄, Ti(NEtMe)₄, Ti(NMe₂)₄, TiCp₂((ⁱPrN)₂C(NHⁱPr)), Ti(Cp)CHT, Ti(CpMe) (OⁱPr)₃, Ti(CpMe₅)(OMe)₃, Ti(NEt₂)₄, Ti(NMe₂)₃(CpMe), and Ti(NMe₂)₃(CpN).

In some embodiments, the metal precursor is a zirconium precursor and deposited metal-containing material comprises zirconium. In some embodiments, the zirconium precursor comprises, consists essentially of, or consists of a metalorganic compound selected from, for example ZrCp₂Me₂, Zn(NMe₂)₄, Zr(NEt₂)₄, Zr(NEtMe)₄, Zr(NEt₂)₄, ZrCp₂(NMe₂)₂, Zr(Cp)(^{t}BuDAD) (OⁱPr), Zr(Cp₂CMe₂)Me₂, Zr(CpMe)(NMe₂)₃, Zr(CpMe)₂Me₂, Zr(CpMe)CHT, Zr(MeAMD)₄, Zr(OⁱPr)₂(dmae)₂, Zr(OⁱPr)₄, Zr(O^{t}Bu)₄ and Zr(thd)₄.

In some embodiments, the metal precursor is a hafnium precursor and deposited metal-containing material comprises hafnium. In some embodiments, the hafnium precursor comprises, consists essentially of, or consists of a metalorganic compound selected from, for example Hf(NEtMe)₄, Hf(NMe₂)₄, Hf(NEt₂)₄, HfCp(NMe₂)₃, Hf(CpMe)₂Me₂, Hf(Cp₂CMe₂)Me(OMe), Hf(CpMe)(NMe₂)₃, Hf(CpMe)₂(mmp)Me, Hf(CpMe)₂(OⁱPr)Me, Hf(dmap)₄, Hf(mmp)₄, Hf(ⁱPrFMD)₂(NMe₂)₂, Hf(NO₃)₄, Hf(OⁱPr)₄ and Hf(O^{t}Bu)₄.

In some embodiments, the metal precursor is a vanadium precursor and deposited metal-containing material comprises vanadium. In some embodiments, the vanadium precursor comprises, consists essentially of, or consists of a metalorganic compound selected from, for example bis(mesitylene)vanadium, bis(toluene)vanadium, and bis(benzene)vanadium, bis(1,3,5-trimethylbenzene)vanadium, bis(ethylbenzene)vanadium, V(CO)₆, bis(ethylbenzene)vanadium, V(NMe₂)₄, V(NEt₂)₄, V(NEtMe)₄, V(ⁱPrAMD)₃, VO(acac)₂ and VO(OⁱPr)₃.

In some embodiments, the metal precursor is a niobium precursor and deposited metal-containing material comprises niobium. In some embodiments, the niobium precursor comprises, consists essentially of, or consists of a metalorganic compound selected from, for example Nb(N^{t}Bu)(NMe₂)₃. Nb(N^{t}Bu)(NEt₂)₃, Nb(N^{t}Bu)(NEtMe)₃, Nb(N^{t}Bu)(NEt₂)₂(Cp), Nb(N^{t}Bu)(NEtMe)₃, Nb(OEt)₅, Nb(OEt)₅, bis(methylbenzene)niobium, bis(ethylbenzene)niobium, bis(1,3,5-trimethylbenzene)niobium and bis(toluene)niobium.

In some embodiments, the metal precursor is a tantalum precursor and deposited metal-containing material comprises tantalum. In some embodiments, the tantalum precursor comprises, consists essentially of, or consists of a metalorganic compound selected from, for example Ta(NMe₂)₅, Ta(NEt₂)₅, Ta(NEt)(NEt₂)₃, Ta(N^{t}Bu)(ⁱPrAMD)₂(NMe₂), Ta(N^{t}Bu) (NEt₂)₃, Ta(OEt)₅, Ta(NEtME)₅, Ta(NⁱPr)(NEtME)₃ and TaCp(N^{t}Bu)(NEt₂)₂.

In some embodiments, the metal precursor is a chromium precursor and deposited metal-containing material comprises chromium. In some embodiments, the chromium precursor comprises, consists essentially of, or consists of a metalorganic compound selected from, for example Bis(benzene)chromium, bis(1,3,5-trimethylbenzene)chromium, tricarbonyl(1,3,5-trimethylbenzene)chromium, Cr(DAD)₂, Cr(acac)₃ and Cr(thd)₃.

In some embodiments, the metal precursor is a molybdenum precursor and deposited metal-containing material comprises molybdenum. In some embodiments, the molybdenum precursor comprises, consists essentially of, or consists of a metalorganic compound selected from, for example MoCp₂Cl₂, MoCp₂H₂, Mo(ⁱPrCp)₂Cl₂, Mo(ⁱPrCp)₂H₂, Mo(EtCp)₂H₂, Mo(CO)₆, Mo(1,3,5-cycloheptatriene)(CO)₃, Mo(N^{t}Bu)₂(NEt₂)₂, Mo(N^{t}Bu)₂(NMe₂)₂, Mo(NMe₂)₄, Mo(N^{t}Bu)₂(ⁱPrAMD)₂, MoCp(CO)₂(NO), Mo(MeCp) (CO)₂(NO), bis(benzene)molybdenum, bis(methylbenzene)molybdenum, bis(ethylbenzene)molybdenum, bis(1,3-dimethylbenzene)molybdenum, bis(1,3,5-trimethylbenzene)molybdenum, tricarbonyl(1,3,5-trimethylbenzene)molybdenum, bis(m-xylene)molybdenum, Mo(CO)₆, Mo(CO)₅P(OMe)₃, and Mo(CO)₅PEt₃.

In some embodiments, the metal precursor is a tungsten precursor and deposited metal-containing material comprises tungsten. In some embodiments, the tungsten precursor comprises, consists essentially of, or consists of a metalorganic compound selected from, for example mesitylene tungsten tricarbonyl, tricarbonylbenzenetungsten, tricarbonyl(1,3,5-trimethylbenzene)tungsten, bis(benzene)tungsten, bis(methylbenzene)tungsten, bis(ethylbenzene)tungsten, bis(1,3-dimethylbenzene)tungsten, bis(1,3,5-trimethylbenzene)molybdenum, W(CO)(₃-hexyne)₃, W(N^{t}Bu)₂(NMe₂)₂, W₂(NMe₂)₆, W(CO)₆, W(N^{t}Bu)₂(ⁱPrAMD)₂, WO₂(^{t}BuAMD)₂, WH₂(ⁱPrCp)₂, WH₂Cp₂ and W(N^{t}Bu)₂(Me₃SiMe)₂.

In the formulas, acac stands for acetylacetonato, AMD for acetamidinato, CHT for cycloheptatrienyl, Cp for cyclopentadienyl, DAD for diazabutadiene (such as N, N′-diisopropyldiazadiene or N, N′-di-tert-butyldiazadiene), dmae for dimethylaminoethoxide, dmap for 1-Dimethylamino-2-propoxide, FMD for formamidinato, mmp for 1-methoxy-2-methyl-2-propoxide, Me for methyl, Et for ethyl, ⁱPr for iso-propyl, ^{t}Bu for tert-butyl and ⁿBu for n-butyl and thd for 2,2,6,6-tetramethyl-3,5-heptanedionato.

### Lewis Acid Reactant

In the methods according to the current disclosure, a Lewis acid reactant is provided into the reaction chamber in a vapor phase. The Lewis acid reactant reacts with the metal precursor to form the material comprising a transition metal on the substrate. Alternatively or in addition, in some embodiments, the Lewis acid reactant reacts with the surface-chemisorbed co-reactant, or a derivative species thereof on the surface.

In some embodiments, the Lewis acid reactant comprises a group 13 element and one or more ligands selected from a halide, an alkoxide, an alkyl, a dialkylamide and combinations thereof. In some embodiments, the group 13 element is boron. In some embodiments, the group 13 element is aluminum. In some embodiments, the group 13 element is gallium. In some embodiments, the halide is selected from a group consisting of a fluoride, a chloride, a bromide, an iodide and combinations thereof. In some embodiments the alkoxide is selected from methoxide, ethoxide, n-propoxide, isopropoxide, n-butoxide, sec-butoxide, isobutoxide, tert-butoxide, cyclopentoxide, cyclohexoxide, phenoxide and combinations thereof. In some embodiments, the alkyl ligand is selected from a group consisting of methyl, ethyl, propyl, isopropyl, butyl, isobutyl, sec-butyl, tert-butyl, pentyl, neo-pentyl, cyclopentyl, cyclohexyl, phenyl and combinations thereof. In some embodiments, the dialkylamide group is selected from a group consisting of dimethylamide, diethylamide, ethylmethylamide, bis(trimethylsilyl)amide, diisopropylamide and combinations thereof.

In some embodiments, the Lewis acid reactant comprises an inorganic halide. In some embodiments, the Lewis acid reactant is selected from a group consisting of metal halides and nonmetal halides. In some embodiments, the inorganic halide is a chloride. In some embodiments, the inorganic halide is a fluoride. In some embodiments, the inorganic halide is a bromide. In some embodiments, the inorganic halide is an iodide. In some embodiments, the inorganic halide is a metal chloride. In some embodiments, the inorganic halide is a metal fluoride. In some embodiments, the inorganic halide is a metal bromide. In some embodiments, the inorganic halide is a metal iodide. In some embodiments, the inorganic halide is a metal halide selected from a group consisting of aluminum chloride, molybdenum chloride, and titanium tetrachloride, gallium trichloride, zirconium tetrachloride, hafnium tetrachloride, tungsten pentachloride, tungsten heptachloride, boron trifluoride, boron trichloride, boron tribromide, boron triiodide, aluminum tribromide, titanium tetrafluoride, titanium tetrabromide, titanium tetraiodide, tantalum pentachloride, niobium pentafluoride, niobium pentachloride, vanadium tetrachloride, vanadium oxytrichloride (VOCl₃).

In some embodiments, the Lewis acid reactant is selected from a group consisting of antimony pentafluoride (SbF₅), boron trifluoride (BF₃), aluminum chloride (AlCl₃), titanium tetrachloride (TiCl₄), tin tetrachloride (SnCl₄), iron(III) chloride (FeCl₃), zinc chloride (ZnCl₂), gallium trichloride (GaCl₃), molybdenum pentachloride (MoCl₅), vanadium tetrachloride (VCl₄), boron trichloride (BCl₃), phosphorus pentachloride (PCl₅), sulfur hexafluoride (SF₆) and iodine pentafluoride (IF₅).

In some embodiments, the Lewis acid reactant is TiCl₄. In some embodiments, the Lewis acid reactant is AlCl₃. In some embodiments, the Lewis acid reactant is MoCl₅. In some embodiments, the Lewis acid reactant is BCl₃.

In some embodiments, a metal alkyl can be used as the Lewis acid reactant. For example, a metal alkyl comprising a group 13 metal bonded to alkyl groups can be used. In some embodiments, the Lewis acid reactant comprises, consists essentially of, or consists of, trialkyl aluminum compound or a trialkyl gallium compound or a trialkyl indium compound. In some embodiments, the Lewis acid reactant comprises, consists essentially of, or consists of, trimethylaluminum, or trimethylindium trimethylgallium.

### Co-Reactant

In some embodiments, a co-reactant is provided into the reaction chamber in a vapor phase. In some embodiments, a deposition cycle comprises providing a co-reactant into the reaction chamber. Without limiting the current disclosure to any specific theory, using a co-reactant in the deposition process in addition to the Lewis acid reactant may lead to the deposition of elemental metal with low carbon impurity. In some embodiments, the co-reactant comprises one halogen atom. In some embodiments, the co-reactant comprises no more than one halogen atom. In some embodiments, the co-reactant comprises two or more halogen atoms. The co-reactant may or may not comprise a group 14 element. In some embodiments, a co-reactant consists of carbon, hydrogen and one or more halogen atoms selected from F, Cl, I and Br. In some embodiments, a co-reactant consists of carbon, oxygen, hydrogen and one or more halogen atoms selected from Cl, I and Br. In some embodiments, a co-reactant consists of silicon, hydrogen and one or more halogen atoms selected from F, Cl, I and Br. In some embodiments, a co-reactant consists of silicon, oxygen, hydrogen and one or more halogen atoms selected from Cl, I and Br. In some embodiments, the co-reactant is selected from a group consisting of halosilanes, alkyl halides and acyl halides. In some embodiments, the co-reactant is pulsed into the reaction chamber at least partially simultaneously with the Lewis acid reactant. In some embodiments, the co-reactant is pulsed into the reaction chamber simultaneously with the Lewis acid reactant.

In some embodiments, the co-reactant comprises a halogen selected from chlorine, bromine and iodine. In some embodiments, the co-reactant comprises an alkyl halide. In some embodiments, the co-reactant comprises an alkyl chloride. In some embodiments, the co-reactant comprises an alkyl bromide. In some embodiments the co-reactant comprises an alkyl iodide. In some embodiments the co-reactant comprises an aryl halide. In some embodiments the co-reactant comprises an aryl chloride. In some embodiments the co-reactant comprises an aryl bromide. In some embodiments the co-reactant comprises an aryl iodide.

In some embodiments, the co-reactant comprises a halogenated organic compound (organohalide). In some embodiments, the co-reactant is selected from a group consisting of alkyl halides and acyl halides. In some embodiments, the halogen of the organohalide, such as an alkyl halide or an acyl halide, is selected from a group consisting of fluorine (F) chlorine (Cl), Bromine (Br) and Iodine (I).

In some embodiments, a co-reactant comprises a hydrocarbon that contains one F, Cl, Br or I atom. In some embodiments, a co-reactant comprises a hydrocarbon that contains at least one halogen atom, each halogen selected independently from F, Cl, Br and I. In some embodiments, the halogen in the co-reactant is chlorine. In some embodiments, the halogen in the co-reactant is bromine. In some embodiments, the halogen in the co-reactant is iodine. In some embodiments, the alkyl halide comprises, consists essentially of, or consists of, iodoethane. In some embodiments, the alkyl halide comprises, consists essentially of, or consists of, chloroethane. In some embodiments, a co-reactant comprises a hydrocarbon that contains two or more chlorine, bromine or iodine atoms. In embodiments, in which the co-reactant comprises at least two halogen atoms, the halogen atoms may be bonded to the same or different carbon atoms. In some embodiments, a co-reactant comprises a hydrocarbon where two or more chlorine, bromine or iodine atoms are bonded to a single carbon atom. In some embodiments, a co-reactant comprises a hydrocarbon where two or more chlorine, bromine or iodine atoms are bonded to different carbon atoms, such as tow different carbon atoms. In some embodiments, at least two halogen atoms in the co-reactant are attached to adjacent carbon atoms of the hydrocarbon. In some embodiments, said carbon atoms are non-adjacent, i.e. the carbon atoms bonded to halogen atoms are not directly bonded to each other.

In some embodiments, the co-reactant comprises a 1,2-dihaloalkane or 1,2-dihaloalkene or 1,2-dihaloalkyne or 1,2-dihaloarene. In some embodiments, the halogen atoms of the co-reactant are the same halogen. In some embodiments, two halogen atoms of the co-reactant are chlorine. In some embodiments, two halogen atoms of the co-reactant are iodine. In some embodiments, the two halogen atoms of the co-reactant are bromine. In some embodiments, the co-reactant comprises 1,2-diiodoethane. In some embodiments, the co-reactant consists essentially of, or consists of 1,2-diiodoethane. In some embodiments, the co-reactant comprises 1,2-dichloroethane. In some embodiments, the co-reactant consists essentially of, or consists of 1,2-dichloroethane.

In some embodiments, the co-reactant has a general formula XₐR_{b}C—CXₐR′_{b}, wherein X is halogen selected from F, Cl, Br and I, R and R′ are independently H or an alkyl group, a and b are independently 1 or 2, so that for each carbon atom a+b=3.

In some embodiments, the co-reactant is selected from alkyl chlorides. In some embodiments, the co-reactant is an alkyl chloride and selected from a group consisting of 1,2-dichloroethane, chloromethane, 2-chloro-2-methylpropane, trichloromethane, 2-methyl-2-chrloro-butane, and tert-butyl chloride.

In some embodiments, the co-reactant comprises an alkyl halide comprising 1,2-diiodoethane or iodobutane. In some embodiments, the co-reactant comprises 1,2-diiodoethane. In some embodiments, the co-reactant comprises iodobutane. In some embodiments, the co-reactant is 1,2-diiodoethane. In some embodiments, the co-reactant is iodobutane. In some embodiments, the co-reactant comprises, consists essentially of, or consists of, iodomethane. In some embodiments, the co-reactant comprises, consists essentially of, or consists of, tert-butyl iodide. In some embodiments, the co-reactant comprises, consists essentially of, or consists of, 2-iodo-2-methylbutane.

In some embodiments the co-reactant comprises an acyl halide. In some embodiments, the halogen in the co-reactant is selected from chlorine, bromine, iodine and fluorine (F). In some embodiments, the co-reactant comprises an acyl chloride. In some embodiments the co-reactant comprises an acyl bromide. In some embodiments the co-reactant comprises an acyl iodide. In some embodiments, the co-reactant comprises an acyl fluoride. In some embodiments, the acyl halide is selected from a group consisting of ethanoyl chloride (CH₃COCl), propionyl chloride (alternatively called propanoyl chloride, CH₃CH2_{C}OCl), butyryl chloride (butanoyl chloride), CH₃CH₂CH₂COCl), benzoyl chloride (C₆H₅COCl) and formyl chloride (methanoyl chloride, HCOCl), acetyl bromide (ethanoyl bromide, CH₃COBr), acetyl fluoride (ethanoyl fluoride, CH₃COF), acetyl bromide, pentanoyl bromide, 2-methylpropanoyl bromide, acetyl iodide, propanoyl bromide, 2,2-dimethylpropanoyl bromide, pivaloyl chloride, pivaloyl bromide, pivaloyl fluoride and pivaloyl iodide.

In some embodiments, the co-reactant comprises a halosilane. In some embodiments, the co-reactant is a halosilane. In some embodiments, the halosilane is an iodosilane. In some embodiments, the halosilane is a chlorosilane. In some embodiments, the halosilane is a bromosilane. In some embodiments, the halosilane is a fluorosilane.

In some embodiments, the halosilane has a general formula SiHₐX_{b}, wherein X is halogen selected from F, Cl, Br and I, and wherein a is 0, 1, 2 or 3, and b is 1, 2, 3 or 4 so that a+b=4. In some embodiments, the halosilane is selected from SiHCl₃, SiH₂Cl₂, SiHI₃, SiH₂I₂, SiHBr₃, SiH₂Br₂, SiHF₃, and SiH₂F₂.

In some embodiments, the co-reactant has a general formula XₐR_{b}Si—SiXₐR′_{b}, wherein X is halogen selected from F, Cl, Br and I, R and R′ are independently H or an alkyl group, a is independently 1, 2 or 3 and b is 0, 1 or 2, so that for each silicon atom a+b=3. In some embodiments, the halosilane is selected from SiHCl₂—SiHCl₂, SiH₂Cl—SiH₂Cl, SiHCl₂—SiH₂Cl, SiCl₃—SiH₂Cl, SiCl₃—SiHCl₂, SiHI₂—SiHI₂, SiH₂I—SiH₂I, SiHI₂—SiH₂I, SiI₃—SiH₂I, SiI₃—SiHI2, SiHBr₂—SiHBr₂, SiH₂Br—SiH₂Br, SiHBr₂—SiH₂Br, SiBr₃—SiH₂Br, SiBr₃—SiHBr₂, SiHF₂—SiHF₂, SiH₂F—SiH₂F, SiHF₂—SiH₂F, SiF₃—SiH₂F, SiF₃—SiHF₂ and SiCl₃—SiCl₃.

In some embodiments, the halosilane is a halogenated trisilane. In some embodiments, the halosilane is selected from Si₃Cl₈ and Si₃Br₈.

### Metal-Containing Materials

The metal-containing material deposited according to the current disclosure comprises a metal from group four, group five or group six of the periodic table of elements. In some embodiments, a metal in the metal-containing material is a group four metal. In some embodiments, a metal in the metal-containing material is a group five metal. In some embodiments, a metal in the metal-containing material is a group six metal. In some embodiments, the metal-containing material contains only one metal element. In some embodiments, the metal-containing material comprises at least one metal. In some embodiments, the metal-containing material comprises at least two metals. In some embodiments, the metal-containing material comprises at least three metals. In some embodiments, the metal-containing material comprises no more than two metals. In some embodiments, the metal-containing material comprises no more than three metals. In this context, impurities or contaminations are not considered as constituents of the material. For example, in embodiments in which a metal-containing material contains only one metal, it is to be understood as being deposited by using only one metal element.

In some embodiments, a metal in the metal containing material is selected from a group consisting of titanium, zirconium and hafnium. In some embodiments, a metal in the metal containing material is selected from a group consisting of vanadium, niobium and tantalum. In some embodiments, a metal in the metal containing material is selected from a group consisting of chromium, molybdenum and tungsten. In some embodiments, a metal in the metal containing material is selected from titanium, zirconium, hafnium, vanadium, niobium, tantalum, chromium, molybdenum and tungsten.

### Metal Carbides

In some embodiments, the material comprising a group four to six transition metal comprises a metal carbide. Thus, in some embodiments, the deposited material is a metal carbide, wherein the metal is a group four metal, group five metal or a group six metal. By a metal carbide is herein meant a material that contains at least one metal and carbon. A metal carbide according to the current disclosure may exhibit at least some degree of crystal structure. In some embodiments, a metal carbide is substantially completely arranged in a crystal structure. In some embodiments, the metal carbide is at least partially amorphous. In some embodiments, the metal carbide is at substantially amorphous. In some embodiments, metal carbides are deposited by providing a metal precursor and a Lewis acid reactant into the reaction chamber. In some embodiments, the metal precursor and the Lewis acid reactant are provided into the reaction chamber alternately and sequentially. In such embodiments, the deposition may take place in ALD regime. In particular, in some embodiments, in which the metal-containing material comprises a metal carbide, the deposition process does not comprise providing a co-reactant into the reaction chamber. Thus, the deposition process may be an AB-type cyclic deposition process, in which two precursors alternate. This can be distinguished from embodiments in which the co-reactant is also provided into the reaction chamber, which can be classified as an ABC-type process.

The dosing of the Lewis acid reactant is important for obtaining the desired composition and properties of the deposited material. The Lewis acid reactant may be provided into the reaction chamber in a short pulse to avoid unwanted reactions. The pulse length of the Lewis acid reactant may be shorter than the length of the metal precursor pulse. For example, the pulse length of the Lewis acid reactant may be less than half of the length of the metal precursor pulse. The pulse length of the Lewis acid reactant may be less than 10% of the length of the metal precursor pulse, or less than 5%, or less than 3% or less than 1% of length of the metal precursor pulse. Alternatively or in addition, the gas flow of the Lewis acid reactant may be reduced compared to that of the metal precursor, and/or of that of the optional co-reactant.

In some embodiments, the metal-containing material comprises substantially only metal and carbon, with trace amounts of impurities. In some embodiments, the metal-containing material comprises substantially only a metal carbide. In some embodiments, the metal-containing material comprises at least 10 at-% metal carbide. In some embodiments, the metal-containing material comprises at least 20 at-% metal carbide. In some embodiments, the metal-containing material comprises at least 30 at-% metal carbide. In some embodiments, the metal-containing material comprises at least 50 at-% metal carbide. In some embodiments, the metal-containing material comprises at least 60 at-% metal carbide. In some embodiments, the metal-containing material comprises at least 75 at-% metal carbide. In some embodiments, the metal-containing material comprises at least 80 at-% metal carbide. In some embodiments, the metal-containing material comprises at least 90 at-% metal carbide. In some embodiments, the metal-containing material comprises at least 95 at-% metal carbide. In some embodiments, the metal-containing material comprises at least 98 at-% metal carbide.

In some embodiments, the metal-containing material comprises titanium carbide, and the metal precursor is a titanium precursor. In some embodiments, the metal-containing material comprises zirconium carbide, and the metal precursor is a zirconium precursor. In some embodiments, the metal-containing material comprises hafnium carbide, and the metal precursor is a hafnium precursor. In some embodiments, the metal-containing material comprises vanadium carbide, and the metal precursor is a vanadium precursor. In some embodiments, the metal-containing material comprises niobium carbide, and the metal precursor is a niobium precursor. In some embodiments, the metal-containing material comprises tantalum carbide, and the metal precursor is a tantalum precursor. In some embodiments, the metal-containing material comprises chromium carbide, and the metal precursor is a chromium precursor. In some embodiments, the metal-containing material comprises molybdenum carbide, and the metal precursor is a molybdenum precursor. In some embodiments, the metal-containing material comprises tungsten carbide, and the metal precursor is a tungsten precursor.

### Elemental Metals

In some embodiments, the material comprising the group four to six transition metal comprises an elemental metal from any of groups 4 to 6 of the periodic table of elements.

In some embodiments, the metal-containing material is elemental titanium, and the metal precursor is a titanium precursor. In some embodiments, the metal-containing material is elemental zirconium, and the metal precursor is a zirconium precursor. In some embodiments, the metal-containing material is elemental hafnium, and the metal precursor is a hafnium precursor. In some embodiments, the metal-containing material is elemental vanadium, and the metal precursor is a vanadium precursor. In some embodiments, the metal-containing material is elemental niobium, and the metal precursor is a niobium precursor. In some embodiments, the metal-containing material is elemental tantalum, and the metal precursor is a tantalum precursor. In some embodiments, the metal-containing material is elemental chromium, and the metal precursor is a chromium precursor. In some embodiments, the metal-containing material is elemental molybdenum, and the metal precursor is a molybdenum precursor. In some embodiments, the metal-containing material is elemental tungsten, and the metal precursor is a tungsten precursor.

Without limiting the current disclosure to any specific theory, the Lewis acid reactant provided into the reaction chamber may react with the metal precursor and/or the co-reactant, or a derivative thereof, chemisorbed on the substrate surface to form metal-containing material on the substrate. In particular, the Lewis acid reactant may be provided into the reaction chamber at least partially simultaneously with the co-reactant, so that it may catalyze the reaction between the co-reactant and the metal precursor. The Lewis acid reactant may be provided to the reaction chamber before providing the co-reactant into the reaction chamber. The Lewis acid reactant may be provided into the reaction chamber in a short pulse. For example, the pulse length of the Lewis acid reactant may be less than half of the length of the co-reactant pulse. The pulse length of the Lewis acid reactant may be less than 20% of the length of the co-reactant pulse. The pulse length of the Lewis acid reactant may be less than 10% of the length of the co-reactant pulse. The pulse length of the Lewis acid reactant may be less than 5% of the length of the co-reactant pulse. The pulse length of the Lewis acid reactant may be less than 2% of the length of the co-reactant pulse. The pulse length of the Lewis acid reactant may be less than 1% of the length of the co-reactant pulse. The pulse length of the Lewis acid reactant may be less than 0.5% of the length of the co-reactant pulse.

In some embodiments, the Lewis acid reactant is provided into the reaction chamber for a duration that is less than 2% of the length of providing the metal precursor into the reaction chamber. This is to be understood that during the deposition process, the aggregate duration of providing the Lewis acid reactant into the reaction chamber is less than 2% of the duration of providing the metal precursor into the reaction chamber. In some embodiments, the Lewis acid reactant is provided into the reaction chamber for a duration that is less than 2% of the length of providing the co-reactant into the reaction chamber. This is to be understood that during the deposition process, the aggregate duration of providing the Lewis acid reactant into the reaction chamber is less than 2% of the duration of providing the co-reactant into the reaction chamber. Similarly, in some embodiments, the Lewis acid reactant is provided into the reaction chamber for a duration that is less than 5% or less than 10% or less than 20% of the length of providing the metal precursor into the reaction chamber. In some embodiments, the Lewis acid reactant is provided into the reaction chamber for a duration that is less than 5% or less than 10% or less than 20% of the length of providing the co-reactant into the reaction chamber.

In some embodiments the substrate is thermally annealed for a period of about 1 to about 15 minutes. In some embodiments the substrate is thermally annealed at a temperature of about 200° C. to about 600° C.

### Drawings

The disclosure is further explained by the following exemplary embodiments depicted in the drawings. The illustrations presented herein are not meant to be actual views of any particular material, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures, devices and assemblies depicted in the drawings may contain additional elements and details, which may be omitted for clarity.

For the sake of brevity, conventional manufacturing, connection, preparation, and other functional aspects of the methods and assemblies described herein may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

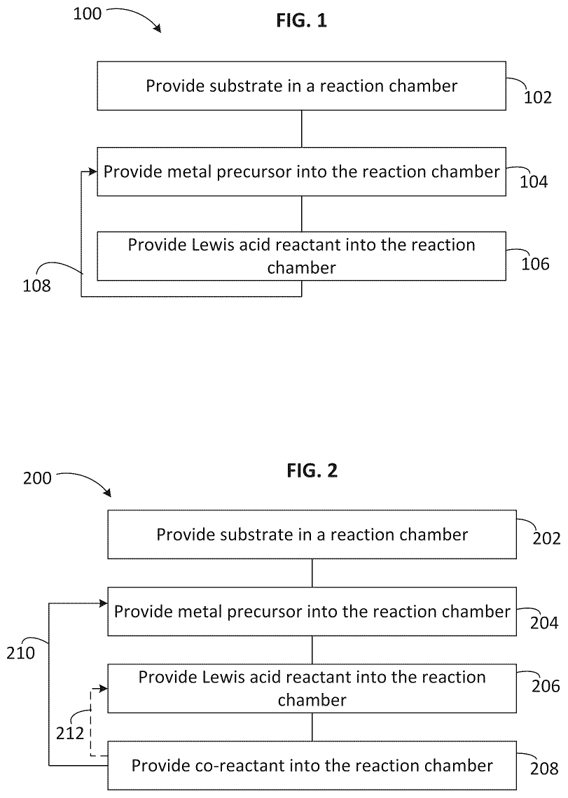

FIG. 1 is a block diagram of an exemplary embodiment of a method 100 according to the current disclosure. First, a substrate is provided in a reaction chamber at block 102. For example, the surface of the substrate may be a dielectric surface, or a metal or a metallic surface. In some embodiments, the substrate surface is a high k surface, such as a hafnium or zirconium oxide surface. In some embodiments, the substrate surface is a silicon-containing dielectric surface, such as a low k surface, such as a silicon oxide, silicon oxycarbide or silicon carbonitride surface. In some embodiments, the substrate surface is a metal surface, for example a copper surface, molybdenum surface, tantalum surface or a tungsten surface. In some embodiments, the substrate surface is a metallic surface, such as a titanium nitride surface. In some embodiments, the substrate surface is an amorphous carbon surface. In some embodiments, the substrate surface is a metal oxide surface or a metal nitride surface (e.g. a metallic surface). In some embodiments, the substrate comprises precleaned silicon or silicon-germanium substrate. In some embodiments, the substrate has a precleaned silicon or silicon-germanium substrate. The substrate may be heated at block 102 prior to providing a metal precursor, a Lewis acid reactant and/or a co-reactant into the reaction chamber.

At block 104, a metal precursor is provided into the reaction chamber in a vapor phase. In exemplary embodiments, the metal precursor is a molybdenum precursor or a niobium precursor as disclosed herein. For example, the molybdenum precursor may comprise, consist essentially of, or consist of, bis(ethylbenzene)molybdenum or bis(1,3,5-trimethylbenzene)niobium. The metal precursor is chemisorbed on the substrate surface. The metal precursor may be provided into the reaction chamber (i.e. pulsed) for about 1 to 30 seconds, for example, about 1.5 seconds, about 10 seconds, about 15 seconds, about 20 seconds or about 25 seconds. The reaction chamber may be purged after a metal precursor pulse. Purging is not indicated in FIG. 1, but it may be optionally included in block 104. The duration of a purge may be from about 0.5 seconds to about 15 seconds, for example about 1 second, about 3 seconds, about 5 seconds or about 8 seconds.

At block 106, a Lewis acid reactant is provided into the reaction chamber in a vapor phase. Without limiting the current disclosure to any specific theory, the Lewis acid reactant pulse may be shorter than the metal precursor pulse. The Lewis acid reactant reacts with the chemisorbed metal precursor or a derivative thereof to form material comprising a group four to six metal (i.e. metal-containing material) on the substrate surface. In an exemplary embodiment, the metal precursor is bis(ethylbenzene)molybdenum and the Lewis acid reactant is TiCl4, and molybdenum carbide is deposited on the substrate surface. In another exemplary embodiment, the metal precursor is bis(1,3,5-trimethylbenzene)niobium, the Lewis acid reactant is AlCl3, and niobium carbide is deposited on the substrate. The reaction chamber may be purged after a Lewis acid reactant pulse. Purging is not indicated in FIG. 1, but it may be optionally included in block 106.

A shorter pulsing time of the Lewis acid reactant than for the metal precursor may be used. In the exemplary embodiments, a pulsing time of 0.01 seconds to about 1.0 for the Lewis acid reactant may be used. For example, a pulsing time of 0.02 seconds, or 0.04 seconds, or 0.08 seconds, or 0.1 seconds may be used. The selected pulsing time may vary depending on the deposition equipment and other conditions used. For example, flow rates from about 80 to about 1,200 sccm, such as from about 100 to about 700 sccm, for example about 100 sccm, about 200 sccm, about 500 sccm or about 600 sccm may be used for the Lewis acid reactant.

The deposition process according to the current disclosure is a cyclic deposition process. Thus, blocks 104 and 106 form a deposition cycle. At loop 108, the deposition cycle is initiated again. The deposition cycle may be repeated as many times as needed to deposit a metal-containing material of desired thickness on the substrate. For example, the deposition cycle may be performed from 2 to about 600 times, or from 2 to about 500 times, or from about 5 to about 200 times, or from about 10 to 400 times. For example, the deposition cycle may be performed about 100 times, about 150 times, about 200 times, about 300 times or about 350 times.

Notably, in embodiments of FIG. 1, a co-reactant is not provided. The resulting metal-containing material in the exemplary embodiments of FIG. 1. is a metal carbide. For example, the metal content of the material may be from about 40 at-% to about 55 at-%, such as about 46 at-% or about 48 at-% or about 50 at-%. The carbon content of the material may be from about 40 at-% to about 60 at-%, for example from about 40 at-% to about 45 at-%, such as about 42 at-% or about 44 at-%. The deposited metal-containing material may contain impurities, such as oxygen, or the constituents of the Lewis acid reactant (such as aluminum, titanium and chlorine in the current examples). The levels of such impurities may be, for example, below about 3.5 at-% for oxygen, below about 1.1. at-% for halogen and below about 2 at-% for the aluminum and titanium.

The resistivity of the metal-containing material depends on the thickness of the deposited layer. However, in some examples, a resistivity of below 270 μOhm cm with a material (i.e. film) thickness of about 37 nm, or below 260 μOhm cm with a film thickness of about 22 nm can be obtained. Even very thin films may be deposited, and in some preliminary examples, a metal-containing material film comprising molybdenum carbide had a resistivity of about 340 μOhm cm at a film thickness of about 3 nm and about 635 μOhm cm at a film thickness of about 2.4 nm. Further, when elemental metal-containing material is deposited on a metal surface with methods according to the current disclosure, the roughness of the surface may be reduced compared to prior art processes. For example, when depositing molybdenum on copper surface, the roughness of the deposited material may be reduced by approximately 74%, and on cobalt surface, the roughness of the deposited material may be reduced by approximately 61%.

The process temperature, such as the temperature of the reaction chamber or the substrate support, may be from about 200° C. to about 450° C. or from about 300° C. to about 400° C., or from about 300° C. to about 3750° C. For example, the process temperature may be about 250° C. or about 300° C. or about 350° C. or about 375° C., such as about 300° C. or about 350° C. Without limiting the current disclosure to any specific theory, the selected temperature may be relevant for the deposition rate and the controllability of the deposition process. The temperature range at which the metal-containing material is deposited in an ALD regime (i.e. ALD window) is broad for the current processes. In some embodiments, the ALD window is from about 250° C. to about 400° C. ALD-type processes allow the deposition of materials conformally, i.e. the rate of deposition on both vertical and horizontal parts of structures is substantially the same. The inventors of the current disclosure confirmed almost 100% conformality on structures having 20 nm critical dimension with depth of 100 nm. Metal-containing material described herein may thus be deposited conformally, confirming that the deposition can be described as ALD.

Although not detailed in the current disclosure, the process may comprise additional steps, for example thermal treatments (such as annealing), intermediate etch-back or post-deposition etching. Although not depicted in FIGS. 1 and 2, it is possible for the blocks of the deposition process to overlap. For example, blocks 104 and 106 may be performed at least partially simultaneously. In some embodiments, blocks 104 and 106 are performed at least partially simultaneously.

FIG. 2 is a block diagram of another exemplary embodiment of a method according to the current disclosure illustrating the deposition of an elemental metal. In contrast to embodiments of FIG. 1, the embodiments of FIG. 2 include providing a co-reactant into the reaction chamber as a part of the deposition process. In embodiments described in FIG. 2, the metal-containing material deposited on the substrate comprises elemental metal, depositing an elemental metal on the substrate is to be understood as depositing a metal from any of groups four to six of the periodic table of elements substantially in elemental form. A metal is deposited in an elemental form if its oxidation state is zero. For example, in the deposition methods of the current disclosure, in which an elemental metal is deposited, at least about 65 at-%, or at least about 80 at-% or at least about 90% of the metal is deposited in elemental form.

In the embodiments of FIG. 2, the process 200 starts similarly to those of FIG. 1. Blocks 202, 204 and 206 correspond to blocks 102, 104 and 106 of FIG. 1, respectively. The embodiments of FIG. 2 differ from those of FIG. 1 in that a co-reactant as described in the current disclosure is provided into the reaction chamber in a vapor phase. As indicated above, the inclusion of a co-reactant dramatically alters the composition of the metal-containing material. Instead of a metal carbide, a material comprising predominantly elemental metal is deposited.

In FIG. 2, the Lewis acid reactant is provided into the reaction chamber at block 206, i.e. before providing a co-reactant into the reaction chamber at block 208. Although blocks 206 and 208 are depicted as separate phases in FIG. 2, they do not need to be discrete. In contrast, FIG. 2 may be read as describing that providing a Lewis acid reactant is initiated before or simultaneously with providing a co-reactant into the reaction chamber. The pulse length of a Lewis acid reactant may be much shorter than that of the metal precursor and co-reactant. The lengths of all of the precursor and reactant pulses depend on the equipment and process parameters used in a particular process.

A co-reactant provided into the reaction chamber 208 is a co-reactant as disclosed herein. In some examples, the co-reactant is 1,2-diiodoethane or iodobutane.

The deposition process according to FIG. 2 is cyclic, and as described above, a deposition cycle—in this case comprising blocks 204, 206 and 208—is repeated as indicated by loop 210 for a predetermined number of times to deposit desired amount of metal-containing material. In some preliminary examples, the deposition cycle is performed about 400 times.

FIG. 2 also contains an optional loop 212 (indicated by dashed arrow). Providing (e.g. pulsing) the Lewis acid reactant and co-reactant can be repeated a predetermined number of times before the metal precursor is re-introduced into the reaction chamber in the next deposition cycle. Loop 212 thus defines a subcycle of the deposition cycle (defined by loop 210), which can be called a master cycle.

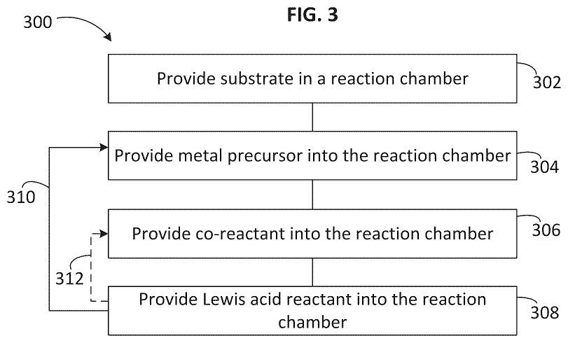

FIG. 3 depicts embodiments similar to FIG. 2, describing a deposition process 300 having blocks 302 and 304 corresponding to blocks 202 and 204 of FIG. 2, respectively. However, as FIG. 3 highlights the option that the co-reactant may be provided (e.g. pulsed) into the reaction chamber before or simultaneously with the Lewis acid reactant, block 306 corresponds to block 208, and block 308 corresponds to block 206. Loop 312 is included to for the optional subcycle modification of the process as in FIG. 2, and loop 310 indicates the cyclic overall character of the process.

Elemental metals deposited according to FIGS. 2 and 3 may contain impurities. The elemental metal materials deposited according to the current disclosure contain low carbon impurities, such as below about 5 at-%, or below about 2.5 at-%. Thus, the metal materials, such as metal films, have properties that may be particularly well suited for certain applications in manufacturing semiconductor devices. For example, when deposited on silicon-based materials, the metal-containing material comprising elemental metal may serve as a contact material. A sharp metal-silicon interface, and in particularly having a low oxygen content can make the methods and materials according to the current disclosure are advantageous in such applications. In some preliminary tests of the processes, a contact resistivity of less than 6×10⁻⁹ Ohm cm² on silicon was observed. When deposited on metal surfaces, such as copper surfaces, reduced roughness and no mixing of metal (such as molybdenum) with the underlying metal (such as copper) was observed.

In some examples, elemental molybdenum is deposited by using bis(ethylbenzene)molybdenum as a metal precursor, iodobutane as a co-reactant and TiCl₄ as the Lewis acid reactant. The reaction chamber is purged after providing each precursor and reactant into the reaction chamber.

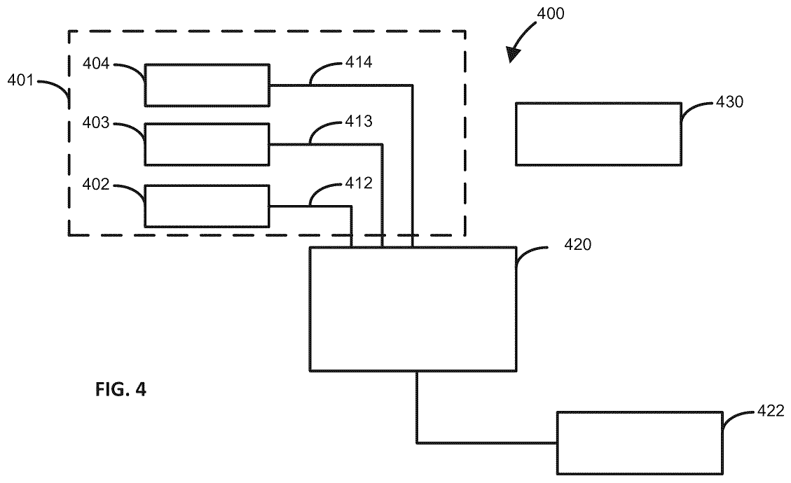

FIG. 4 is a schematic drawing of an embodiment of a semiconductor processing assembly according to the current disclosure. In one aspect, a semiconductor processing assembly constructed and arranged to perform a method according to the current disclosure is disclosed.

Thus, a semiconductor processing assembly 400 for depositing a metal-containing material, particularly elemental metal or metal carbide, on a substrate is disclosed. The semiconductor processing assembly 400 comprises one or more reaction chambers 420 constructed and arranged to hold the substrate, and a precursor injector system 401 constructed and arranged to provide a metal precursor comprising a metalorganic compound into the reaction chamber 420 in a vapor phase. The semiconductor processing assembly 400 further comprises a metal precursor source vessel 402 and a Lewis acid reactant source vessel 403. The precursor injector system 401 is constructed and arranged to provide the metal precursor and the Lewis acid reactant into the reaction chamber 420 in a vapor phase. The metal precursor and the Lewis acid reactant may be provided into the reaction chamber alternately and sequentially to form a metal-containing material, in particular metal carbide on the substrate.

The semiconductor processing assembly 400 further comprises an optional co-reactant source vessel 404 constructed and arranged to contain a co-reactant according to the current disclosure. The semiconductor processing assembly 400 is constructed and arranged to provide the co-reactant via the precursor injector system 401 into the reaction chamber 420 for forming a metal-containing material, in particular elemental metal-containing material on the substrate.

The processing assembly 400 may comprise optional further source vessels (not shown) constructed and arranged to contain additional reactants used in the processing of the substrate. For example, a further source vessel may be constructed and arranged to hold a further metal precursor or an etchant.

The processing assembly 400 is configured and arranged to perform a method as described herein. In the illustrated example, the semiconductor processing assembly 400 includes one or more reaction chambers 420, a precursor injector system 401, source vessels 402, 403, optional and further source vessels (such as a co-reactant source vessel 404), an exhaust source 422, and a controller 430. The processing assembly 400 may comprise one or more additional gas sources (not shown), such as an inert gas source, a carrier gas source and/or a purge gas source. Reaction chamber 420 can include any suitable reaction chamber, such as an ALD or CVD reaction chamber as described herein.

The metal precursor source vessel 402 can include a vessel and a metal precursor as described herein—alone or mixed with one or more carrier (e.g., inert) gases. The reactant source vessel 403 can include a vessel and a reactant as described herein—alone or mixed with one or more carrier (e.g., inert) gases. Thus, although illustrated with three source vessels 402-404, a processing assembly 400 can include any suitable number of source vessels. Source vessels 402-404 can be coupled to reaction chamber 420 via lines 412-414, which can each include flow controllers, valves, heaters, and the like. In some embodiments, each of the source vessels 402-404 may be independently heated or kept at ambient temperature. In some embodiments, a source vessel is heated so that a precursor or a reactant reaches a suitable temperature for vaporization.

Exhaust source 422 can include one or more vacuum pumps.

Controller 430 includes electronic circuitry and software to selectively operate valves, manifolds, heaters, pumps and other components included in the processing assembly 400. The controller is programmed to execute a method as disclosed herein. Such circuitry and components operate to introduce precursors, reactants and other gases from the respective sources. Controller 430 can control timing of gas pulse sequences, temperature of the substrate and/or reaction chamber 420, pressure within the reaction chamber 420, and various other operations to provide proper operation of the processing assembly 400. Controller 430 can include control software to electrically or pneumatically control valves to control flow of precursors, reactants and other gases into and out of the reaction chamber 420. Controller 430 can include modules such as a software or hardware component, which performs certain tasks.

Other configurations of processing assembly 400 are possible, including different numbers and kinds of precursor and source vessels. For example, a reaction chamber 420 may comprise more than one, such as two or four, deposition stations. Such a multi-station configuration may have advantages if, for example, inhibition, passivation, deposition and/or etching are to be performed in the same reaction chamber. Further, it will be appreciated that there are many arrangements of valves, conduits, precursor sources, and reactant sources that may be used to accomplish the goal of feeding gases into reaction chamber 420 in a coordinated manner. Further, as a schematic representation of a processing assembly 400, many components have been omitted for simplicity of illustration, and such components may include, for example, various valves, manifolds, purifiers, heaters, containers, vents, and/or bypasses.

During operation of processing assembly 400, substrates, such as semiconductor wafers (not illustrated), are transferred from, e.g., a substrate handling system to reaction chamber 420. Once substrate(s) are transferred to reaction chamber 420 (i.e. they are provided in the reaction chamber 420), one or more gases from gas sources, such as precursors, reactants, carrier gases, and/or purge gases, are introduced into reaction chamber 420.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject-matter of the present disclosure includes all novel and nonobvious combinations and sub-combinations of the various methods and assemblies, and other features, functions, acts, and/or properties disclosed herein, as well as any and all equivalents thereof.

1. A method for depositing a material comprising a group four to six transition metal on a substrate by a cyclic deposition process, the method comprising
providing a substrate in a reactor chamber;
providing a metal precursor comprising a metalorganic compound into the reaction chamber in a vapor phase; and
providing a Lewis acid reactant into the reaction chamber in a vapor phase to react with the metal precursor; and to form the material comprising the transition metal from any of groups four to six on the substrate.

2. The method of claim 1, further comprising providing a co-reactant into the reaction chamber in a vapor phase.

3. The method of claim 1, wherein the metalorganic compound comprises a metal selected from a group consisting of vanadium, niobium, tantalum, chromium, molybdenum and tungsten.

4. The method of claim 1, wherein the metal precursor comprises a zero-valence metalorganic compound.

5. The method of claim 1, wherein the metal precursor comprises a bis-arene complex.

6. The method of claim 1, wherein the Lewis acid reactant comprises an inorganic halide.

7. The method of claim 6, wherein the Lewis acid reactant is selected from a group consisting of metal halides and nonmetal halides.

8. The method of any of claims 6, wherein the inorganic halide is a chloride.

9. The method of claim 6, wherein the inorganic halide is a metal halide selected from a group consisting of aluminum chloride, molybdenum chloride, iron chloride, and titanium tetrachloride.

10. The method of claim 1, wherein the Lewis acid reactant comprises a group 13 element and one or more ligands selected from a halide, an alkoxide, an alkyl, a dialkylamide and combinations thereof.

11. The method of claim 1, wherein the material comprising a group four to six transition metal comprises a metal carbide.

12. The method of claim 2, wherein the co-reactant is selected from a group consisting of halosilanes, alkyl halides and acyl halides.

13. The method of claim 12, wherein the co-reactant comprises an alkyl halide comprising 1,2-diiodoethane or iodobutane.

14. The method of claim 12, wherein the co-reactant is selected from alkyl chlorides.

15. The method of claim 14, wherein the co-reactant is an alkyl chloride and selected from a group consisting of 1,2-dichloroethane, chloromethane, 2-chloro-2-methylpropane, trichloromethane, 2-methyl-2-chrloro-butane, and tert-butyl chloride.

16. The method of claim 12, wherein the material comprising the group four to six transition metal comprises an elemental metal from any of groups 4 to 6 of the periodic table of elements.

17. The method of claim 2, wherein the metal precursor, the Lewis acid reactant, and the co-reactant are supplied in pulses and the reaction chamber is purged after consecutive pulses of the Lewis acid reactant and the co-reactant.

18. The method of claim 2, wherein the Lewis acid reactant and the co-reactant are provided in any order.

19. The method of claim 1, wherein the Lewis acid reactant is provided into the reaction chamber for a duration that is less than 2% of the length of providing the metal precursor into the reaction chamber.

20. The method of claim 1, wherein the process temperature is between about 150-400° C.

21. The method of claim 1, wherein the substrate comprises precleaned silicon or silicon-germanium substrate.

22. A semiconductor processing assembly constructed and arranged to perform a method according to any of claim 1.
